(19) United States
(12) Patent Application Publication
(10) Pub. No.: US 2014/0043054 A1
(43) Pub. Date: Feb. 13, 2014

(54) VERTICAL PROBES FOR MULTI-PITCH FULL GRID CONTACT ARRAY

(71) Applicant: FormFactor, Inc., Livermore, CA (US)

(72) Inventor: January Kister, Portola Valley, CA (US)

(73) Assignee: FormFactor, Inc., Livermore, CA (US)

(21) Appl. No.: 13/963,567

(22) Filed: Aug. 9, 2013

Related U.S. Application Data
(60) Provisional application No. 61/681,558, filed on Aug. 9, 2012.

(51) Int. Cl. G01R 1/067

(52) U.S. Cl. CPC G01R 1/06711
USPC 324/754.03

(57) ABSTRACT

A testing method (and the probes used) comprising providing one or more probes each comprising: a body portion which is substantially straight; an extended portion extending from the body portion and comprising at least two separate probe portions; and a tip portion at the opposite end of the extended portion; and contacting an object to be tested with the one or more probes.

### CROSS-REFERENCE TO RELATED APPLICATIONS

This application claims priority to and the benefit of the filing of U.S. Provisional Patent Application Ser. No. 61/681,558, entitled “Vertical Probes for Multi-Pitch Full Grid Contact Array”, filed on Aug. 9, 2012, and the specification and claims thereof are incorporated herein by reference.

### STATEMENT REGARDING FEDERALLY SPONSORED RESEARCH OR DEVELOPMENT

Not Applicable.

### INCORPORATION BY REFERENCE OF MATERIAL SUBMITTED ON A COMPACT DISC

Not Applicable.

### COPYRIGHTED MATERIAL

Not Applicable.

### BACKGROUND OF THE INVENTION

1. Field of the Invention (Technical Field)

The present invention relates to testing probes and their use and manufacture.

2. Description of Related Art

As integrated circuit (IC) technology evolves, new problems must be addressed in connection with probes for testing ICs. FIG. 1 shows an example of a recent development in IC technology. This figure shows a top view of an IC contact array that can arise in practice, and for which it would be desirable to provide probes. This contact array is a full grid array (i.e., 2-dimensional), and has regions of significantly different contact pitch adjacent to each other (e.g., large pitch region 102 and small pitch region 104). Such contact arrays can arise in connection with through-silicon via technology. Here large and small are relative terms, and both pitches can be small when related to conventional probe dimensions (e.g., large pitch 90-100 μm, small pitch 45-50 μm). Typically, the large pitch contacts include power and ground contacts, and must be probed with probes that can handle at least 1 A currents, while the small pitch contacts are only input/output contacts (i.e., no power/ground contacts), and can be probed with probes that can handle at least 0.5 A currents.

It is challenging to probe such a contact array with vertical probes. It is highly desirable for all probes in the probe array to have the same length. However, simply scaling the size of conventional probe designs suitable for the various pitches of the contact array will not work well in practice. If probes suitable for the small pitch are scaled to have the same length as the large pitch probes, the resulting scaled probes will have insufficient contact force and current carrying capacity (e.g., 0.1 g contact force (CF), and 0.1 A current carrying capacity (CCC), which are both much too low). If probes suitable for the large pitch are scaled to have the same length as the small pitch probes, the resulting probes will be too stiff, and provide an excessive contact force. The present invention solves this challenge.

### BRIEF SUMMARY OF THE INVENTION

The present invention is of a testing method (and the probes used) comprising: providing one or more probes each comprising: a body portion which is substantially straight; an extended portion extending from the body portion and comprising at least two separate probe portions; and a tip portion at the opposite end of the extended portion; and contacting an object to be tested with the one or more probes. In the preferred embodiment, a conductive tie between the at least two probe portions at approximately a midpoint of the extended portion can be employed, as well as a conductive tie at the tip portion (preferably additionally comprising one or more skates). One or both of the extended portion and the tip portion is laser cut. The tip portion may be created prior to the laser cut of the extended portion. Preferably, the extended portion is curved.

Further scope of applicability of the present invention will be set forth in part in the detailed description to follow, taken in conjunction with the accompanying drawings, and in part will become apparent to those skilled in the art upon examination of the following, or may be learned by practice of the invention. The objects and advantages of the invention may be realized and attained by means of the instrumentalities and combinations particularly pointed out in the appended claims.

### BRIEF DESCRIPTION OF THE SEVERAL VIEWS OF THE DRAWINGS

The accompanying drawings, which are incorporated into and form a part of the specification, illustrate one or more embodiments of the present invention and, together with the description, serve to explain the principles of the invention. The drawings are only for the purpose of illustrating one or more preferred embodiments of the invention and are not to be construed as limiting the invention. In the drawings:

FIG. 1 is an example contact array of a type for which the present invention is useful;

FIG. 2 provides a comparison between existing probes and a probe according to the invention; and

FIGS. 3-5 illustrate alternative embodiments of the vertical probe of the invention.

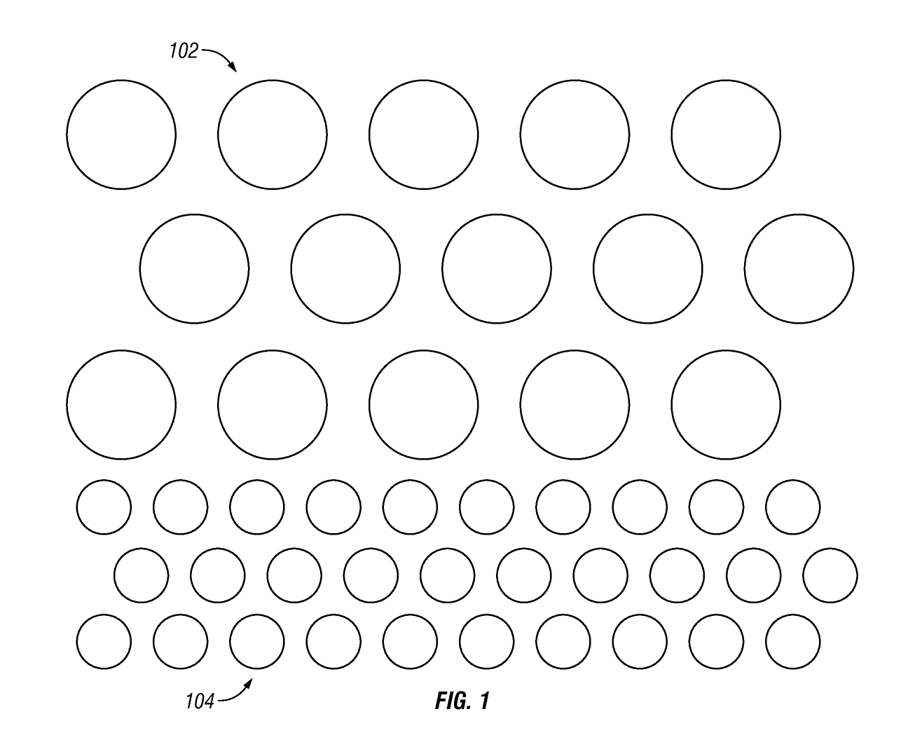

### DETAILED DESCRIPTION OF THE INVENTION

The present invention addresses the problems noted above by changing the mechanical design of preferably the large pitch probes. More specifically, a split-probe design is introduced, where part of the central portion of the probe is removed to provide a probe that is split into two (or more) sections along part(s) of its length. Precision laser fabrication can be employed to create such probe shapes. This splitting can be used to reduce the mechanical stiffness of a scaled large-pitch probe such that its contact force is appropriate for probing. Preferably, the probe array is designed such that all probes (i.e., the small-pitch probes and the scaled and split large-pitch probes) have both the same length and the same contact force per unit area (F/A), because probe tip wear depends on F/A, and it is desirable for all probes to wear at the same rate. In cases where the probe tips have reduced-width sections (which can be referred to as skates), adjusting the skate width can be employed to help equalize F/A for the various probes in the probe array.

For example, one can use the invention with the larger probe in a 45 μm pitch plus 90 μm pitch application. A tie can be included at the “belly” (or below or above) of the device so that the two probes will be less susceptible to overheating. The tip bases can be tied together to form a common tip base. A skate preferably extends from the common base, which would be longer in the scrub direction to equalize the wear with the 45 μm pitch probe. Alternatively, the two tips and skates can be kept separate if useful for stress reduction, with each tip having its own skate the same size as the 45 μm pitch probe. Skates can be centered or offset on the tips.

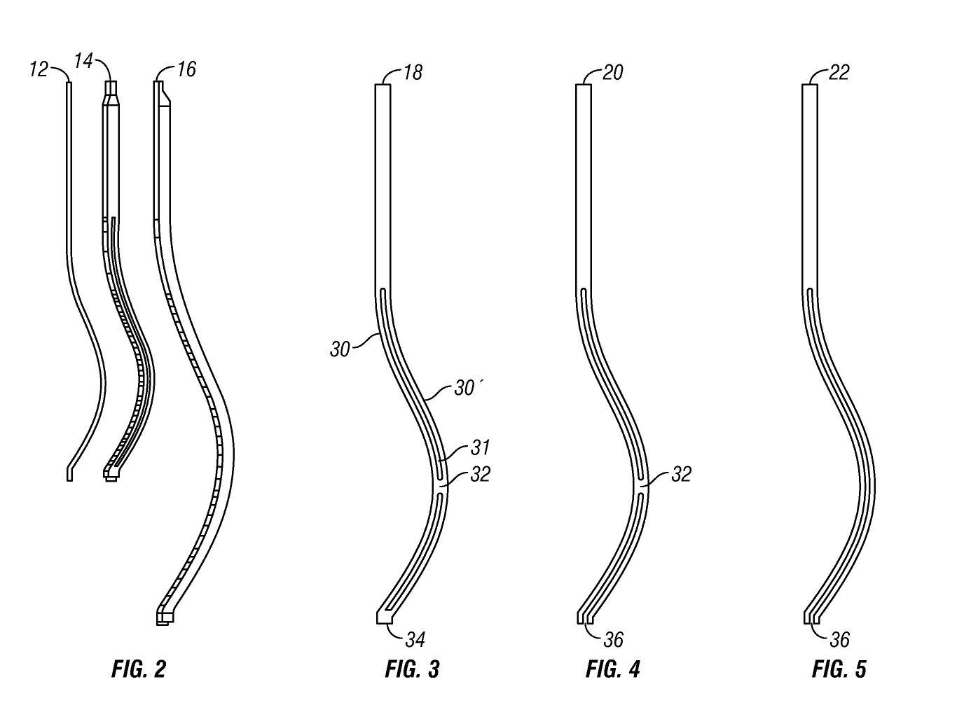

Referring to FIG. 2, comparison is made between existing probes of two sizes, 12,16 with an inventive probe 14. FIG. 3 shows embodiment 18, comprising probe pair 30,30′ with tie 32 near the belly portion 31 of the probe, as well as a tie 34 (preferably with skate) at the tips of the probe pair. FIG. 4 shows embodiment 20 shown lacking a tie at the tips 36 (which can then have or lack their own skates). FIG. 5 shows embodiment 22, which also lacks a tie at the belly portion. Note that probe 14 of FIG. 2 is also shown lacking a tie at or near the belly portion.

A preferred method for making probes according to the invention would be as follows: Start with a metal foil that has alignment features for future processing. The tip feature can be created using two-sided etching of spring material (e.g., BeCu) followed by plating the tip with desirable contactor material (Rh, Pd, etc.). Another option is to start with the tip feature and the foil created through MEMS/Multi-layer metal plating/deposition (including sputtering). This allows for accurate tip feature creation coated with such metals as Rh, Pd, etc. The same process can be applied to creation of the distal end of the probe. The body of the probe is laser cut after the tip/distal end are made. A picosecond laser is preferred. The tip(s), skate(s), and distal end can also be formed by laser cutting.

Note that in the specification and claims, “about” or “approximately” means within twenty percent (20%) of the numerical amount cited.

Although the invention has been described in detail with particular reference to these preferred embodiments, other embodiments can achieve the same results. Variations and modifications of the present invention will be obvious to those skilled in the art and it is intended to cover in the appended claims all such modifications and equivalents. The entire disclosures of all references, applications, patents, and publications cited above are hereby incorporated by reference.

What is claimed is:

1. A probe comprising:
a body portion which is substantially straight;
an extended portion extending from said body portion and comprising at least two separate probe portions; and
a tip portion at an opposite end of said extended portion.

2. The probe of claim 1 additionally comprising a conductive tie between said at least two probe portions at approximately a midpoint of said extended portion.

3. The probe of claim 2 additionally comprising a conductive tie at said tip portion.

4. The probe of claim 3 additionally comprising a skate on said conductive tie at said tip portion.

5. The probe of claim 1 additionally comprising a conductive tie at said tip portion.

6. The probe of claim 5 additionally comprising a skate on said conductive tie at said tip portion.

7. The probe of claim 1 additionally comprising one or more skates on said tip portion.

8. The probe of claim 1 wherein one or both of said extended portion and said tip portion is laser cut.

9. The probe of claim 8 wherein said tip portion is created prior to the laser cut of said extended portion.

10. The probe of claim 1 wherein said extended portion is curved.

11. A testing method comprising:
providing one or more probes each comprising:
a body portion which is substantially straight;
an extended portion extending from the body portion and comprising at least two separate probe portions; and
a tip portion at the opposite end of the extended portion; and
contacting an object to be tested with the one or more probes.

12. The method of claim 11 additionally comprising providing a conductive tie between the at least two probe portions at approximately a midpoint of the extended portion.

13. The method of claim 12 additionally comprising providing a conductive tie at the tip portion.

14. The method of claim 13 additionally comprising providing a skate on the conductive tie at the tip portion.

15. The method of claim 11 additionally comprising providing a conductive tie at the tip portion.

16. The method of claim 15 additionally comprising providing a skate on the conductive tie at the tip portion.

17. The method of claim 11 additionally comprising providing one or more skates on the tip portion.

18. The method of claim 1 wherein one or both of the extended portion and the tip portion is laser cut.

19. The method of claim 8 wherein the tip portion is created prior to the laser cut of the extended portion.

20. The method of claim 11 wherein the extended portion is curved.
